(19) United States
(12) Patent Application Publication
(10) Pub. No.: US 2004/0130017 A1
(43) Pub. Date: Jul. 8, 2004

(54) Stacked layer type semiconductor device and its manufacturing method

(75) Inventor: Takakazu Fukumoto, Tokyo (JP)

Correspondence Address: McDERMOTT, WILL & EMERY, 600 13th Street, N.W., Washington, DC, 20005-3096, US

(73) Assignee: RENESAS TECHNOLOGY CORP.

(21) Appl. No.: 10/739,306

(22) Filed: Dec. 19, 2003

(30) Foreign Application Priority Data
Dec. 20, 2002 (JP) 2002-369513

(51) Int. Cl. H01L 23/02

(52) U.S. Cl. 257/686

(57) ABSTRACT

A multi-layered substrate comprising a plurality of substrates stacked with an insulation layer in between. One or more semiconductor chips arranged within the insulation layer lying between a plurality of substrates. The substrates constitute the connection pads for the semiconductor chips, and connection pins to electrically connect the connection pads of the semiconductor chips.

### BACKGROUND OF THE INVENTION

1. Field of the Invention

The present invention relates to the technology of devising improvement of the mounting density of semiconductor devices on a substrate.

2. Description of the Related Art

Conventionally, various technologies of stacking and mounting semiconductor devices on a substrate have been proposed, in order to improve the mounting density of semiconductors mounted on the substrate. For example, refer to Japanese Patent Publications (unexamined) Nos. 04-367261 and 2001-168255.

Generally, it is preferable that the thickness of the substrate with semiconductor devices mounted thereon is thin. According to the conventional technologies, the thickness of plastic resin enclosing the semiconductor chip prevents changing the thickness of the substrate to a thin type. While it is possible to devise the way to make the substrate thin if semiconductor chips are mounted directly on the substrate, it is difficult to increase the mounting density by stacking a separate semiconductor chip on a semiconductor chip. Also, in the case of mounting semiconductors directly on the substrate, problems occur where aberration of the positions of the semiconductor chips tends to happen due to warping of the substrate and/or expansion and contraction caused by temperature change.

### SUMMARY OF THE INVENTION

Accordingly, it is an object of the present invention to provide a stacked layer type semiconductor device and its manufacturing method which realizes precise mounting of semiconductor chips onto a substrate, improvement of mounting density, and thinning thickness of the whole substrate with the semiconductor chips mounted thereon.

According to a first aspect of the present invention, there is provided a stacked layer type semiconductor device comprising: a multi-layered substrate including a plurality of substrates stacked with an insulation layer in between; a semiconductor chip having a connection pad arranged within the insulation layer lying between said plurality of substrates; and a connection pin to electrically connect the connection pads of one substrate and the other facing substrate.

According to a second aspect of the present invention, there is provided a method of manufacturing a stacked layer type semiconductor device, comprising the steps of stacking a first electrically insulating layer in a non solidified state over the surface of a first substrate with a plurality of connection pads arranged thereon; arranging a semiconductor chip with a plurality of connection pins mounted thereon so as to have respective connection pins positioned on the corresponding connection pads of the first substrate; covering the upper portion of the semiconductor chip with a second electrically insulating layer in a non solidified state; and stacking a second substrate on the electrically insulating layer and having the respective connecting pins penetrate through the first electrically insulating layer and electrically connect to the corresponding connecting pads of the first substrate by applying a force facing the first substrate and the second substrate.

By having a force applied to reduce the space between the substrates, the connection pins for the semiconductor chip penetrate the aforementioned solidified resin film and are connected to the corresponding connection pads of the facing substrate. By having an insulating layer lie between the semiconductor chip and the substrate, short-circuiting of the circuit of the semiconductor chip and the circuit of the substrate is prevented.

For example, in the case that prepreg having electrically insulating characteristics and thermal solidifying characteristics is used as the aforementioned resin film in a non-solidified state, the application of heat makes the substrates adhere to each other, and, with the resin solidified, it becomes possible to have the semiconductor chips fixed between said substrates.

Also, it is conceivable to use, as the resin film in a non-solidified state, a type of resin that solidifies with passage of time. Also, if, as a result of taking into consideration thermal expansion rate, etc., of the substrate, aberration of the positions of the semiconductor chips can be controlled within the allowable range, it is conceivable to use the non-solidified state resin film as it is, i.e., in a non-solidified state. The reason is that this enables handling warping of the substrate more flexibly.

As stated above, by having the semiconductor chips directly mounted on the substrate constituting the multi-layered substrate, it is possible to make the substrate as a whole with said semiconductor chips mounted thereon thin, and devise, by sandwiching the semiconductor chips in each layer of the multi-layered substrate, in substance, a change to multi layering of the semiconductor chips, and at the same time, by encasing the semiconductor chip in an electrically insulating film, it is possible to prevent aberration of the semiconductor chip from its mounting position, due to warping of the substrate and/or expansion/contraction of the substrate caused by temperature change.

Also, by having the semiconductor chip encased in the electrically insulating film between the multi-layered substrates, it makes it possible to, in substance, stack the layers of the semiconductor chips without almost increasing the thickness of the multi-layered substrate. Furthermore, if semiconductor chips with a circuit and connection pads provided on both surfaces are made available to be sandwiched between the multi-layered substrates, the mounting density will improve all the more.

### BRIEF DESCRIPTION OF THE DRAWINGS

FIG. 1A is a perspective view of a semiconductor chip with connection pins on its connection pads;

FIG. 1B is a plan view of one of connection pins;

FIG. 1C is a cross sectional view taken along line C-C′ of FIG. 1B;

FIG. 2A is a cross sectional view showing a first state of manufacturing a connection pin;

FIG. 2B is a cross sectional view showing a second state of manufacturing a connection pin;

FIG. 3 is a perspective view describing the method of forming the stacked layer type semiconductor device relating to Embodiment 1.

FIG. 4 is a cross sectional view of a portion of the stacked layer type semiconductor device relating to Embodiment 1.

FIG. 5 is a cross sectional view of a portion of the variation example 1 of the stacked layer type semiconductor device relating to Embodiment 1.

FIG. 6A is a plan view of a portion of the variation example 2 of the stacked layer type semiconductor device relating to Embodiment 1.

FIG. 6B is a cross sectional view of a portion of the variation example 2 of the stacked layer type semiconductor device relating to Embodiment 1.

FIG. 7A is a perspective view of the silicon wafer for describing a manufacturing method of the semiconductor chip relating to Embodiment 2.

FIG. 7B is a cross sectional view of the silicon wafer of FIG. 7A.

FIG. 7C is a cross sectional view showing a first state of manufacturing the semiconductor device relating to Embodiment 2.

FIG. 7D is a cross sectional view showing a second state of manufacturing the semiconductor device relating to Embodiment 2.

FIG. 8A is a cross sectional view showing a first state of manufacturing the semiconductor device relating to another method of Embodiment 2.

FIG. 8B is a cross sectional view showing a second state of manufacturing the semiconductor device relating to another method of Embodiment 2.

FIG. 8C is a cross sectional view showing a final state of manufacturing the semiconductor device relating to another method of Embodiment 2.

FIG. 9 is a cross sectional view of a portion of the semiconductor device relating to Embodiment 2.

FIG. 10 is a cross sectional view of a portion of a variation example of the semiconductor device relating to Embodiment 2.

### DETAILED DESCRIPTION OF THE PREFERRED EMBODIMENTS

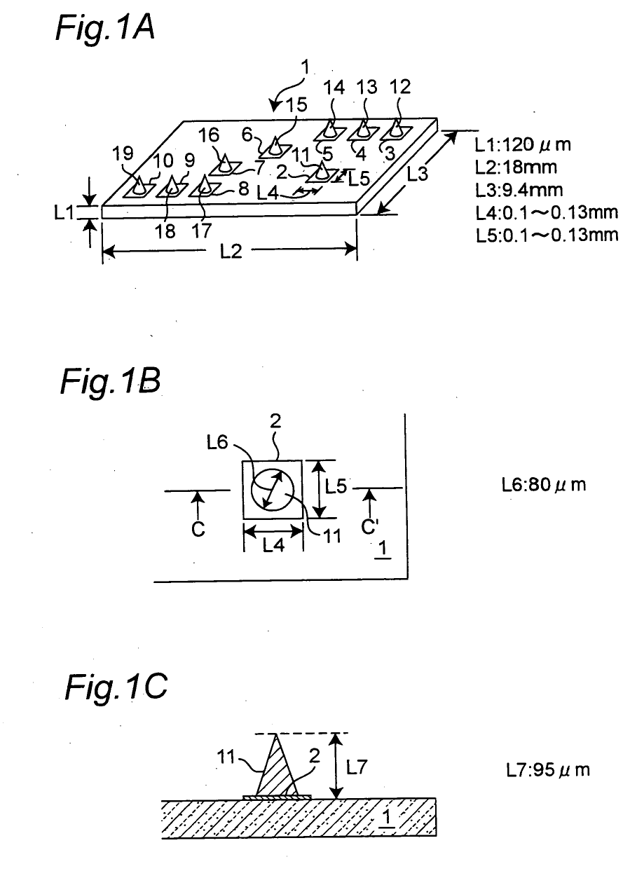

(1) Embodiment 1 FIG. 1A is a diagram in which the surface is turned upward, such surface having the connection pads 2-10 of the semiconductor chip 1 used for the stacked layer type semiconductor device 55 in relation to the Embodiment 1. On the respective connection pads 2-10 of the same size, metal connection pins 11-19 of about the same size and configuration are mounted. The semiconductor chip 1 has the thickness L1 of 120 μm, and the width L2×the length L3 is 18 mm×9.4 mm. The connection pad 2 to be prepared is of the size having the width L4×the length L5 being 0.1 mm² to 0.13 mm².

FIG. 1B is a diagram of the connection pin 11 mounted on the connection pad 2, viewed from above. The diameter L6 of the connection pin 11 at the position in contact with the connection pad 2 is approximately 80 μm.

FIG. 1C is a cross sectional diagram at C-C′ of FIG. 1B. The height of the connection pin 11 is approximately 951 μm. The value of the height of the connection pin 11, as explained later, is made larger than the thickness of prepreg provided between the semiconductor chip 1 and the substrate for mounting and is used as a resin film in a non solidified state which has electrically insulating characteristics and thermal solidifying characteristics.

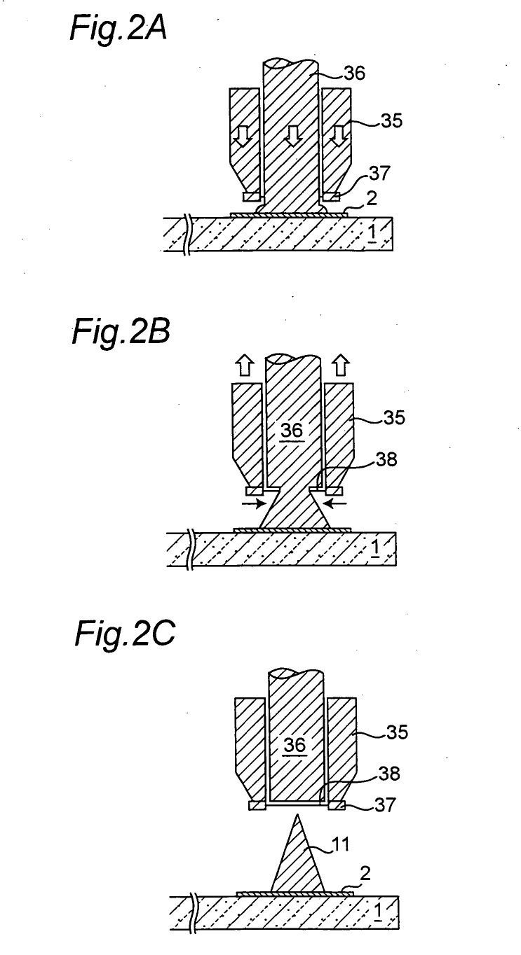

The connection pin 11 having the aforementioned size and configuration may be formed by utilizing a wire-bonding device in which thermo-sonic bonding technology, which is one of the wire-bonding methods, is used. As specifically shown in FIG. 2A, a fine gold wire 36 having a diameter of 60-80 μm is set on the guide arm 35 for the wire of the wire-bonding device in which the thermo-sonic bonding technology is used, and, additionally, a device in which the cutter 37 of a squeezing valve type is provided at the tip portion of the wire guide arm 35. First, using the arm 35 having the structure described above, the gold fine wire 36 is coupled to the connection pad 2 on the substrate 1.

Next, as shown in FIG. 2B, the arm 35 is pulled away from the substrate as the gold wire 36 is extruded from the arm 35, and, at the same time, the squeezing valve shaped cutter 35 is operated. With this, the gold wire 36 is cut, as it is squeezed.

By having the arm 35 move and the squeezing valve type cutter 37 operate, the connection pin 11 of a conical shape is formed.

Also, with respect to manufacturing of the connection pin 11, considering that a general wire-bonding device in which the thermo-sonic bonding technology is used is able to mount a fine gold wire or aluminum fine wire having the diameter of 30-50 μm to the connection pad of approximately 60 μm×100 μm on the semiconductor chip, it is understood that the arm 35 having the aforementioned structure may be realized without any problem from point of view of precision in manufacturing.

It is preferable that the configuration of the connection pin 11 is such that it has a pointed shape in the direction away from the connection pad 2 so as to easily puncture the prepreg which is a resin in a non-solidified state and is electrically insulating and having thermal solidifying characteristics; however, it does not necessarily have to be a conical shape as shown in FIG. 1C but may be of a different shape so long as it can puncture the prepreg film and be coupled to the connection pad of the facing substrate.

For example, the configuration of the connection pin 11 may be a cylindrical shape cut diagonally as in the case in which a cutter is gradually pushed out from one side to make a cut, rather than using a squeezing shaped cutter, when the arm 35 is pulled away from the connection pad 2 as said fine gold wire 36 is extruded after the fine gold wire 36 is mounted to the connection pad 2. Also, it may be a nearly complete cylindrical shape or furthermore, it may be a semi-hemispherical shape also, as in the case in which the fine gold wire 36 is mounted to the metal pad 2, and after extrusion of the fine gold wire of the required length, cutting is conducted by the squeezing valve type cutter 37, having the fine wire 36 from the arm 35 stopped from being extruded.

Also, if it is possible to mount the connection pin 11 to the connection pad so that it does not contact the wires in the periphery, and if the prepreg can be surely punctured, any conductive metal or alloy other than gold, e.g. aluminum, may be used as the connection pin.

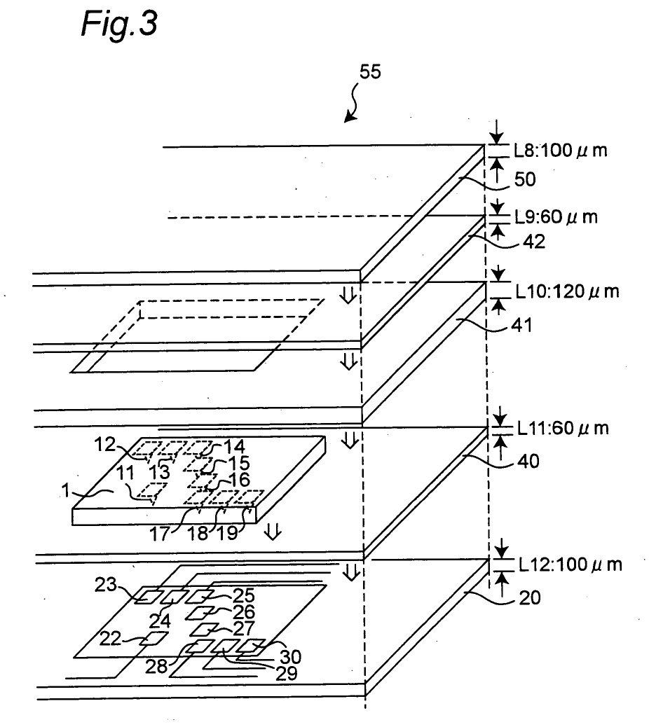

FIG. 3 is a diagram showing a manufacturing method for the multi-layered type semiconductor device 55 relating to the Embodiment 1. For said multi-layered semiconductor device 55, the semiconductor chip 1 is completely encased in the prepregs 40,41,42 arranged between the substrate 20 and substrate 50 having wiring on both surfaces. Specifically, after the substrate having the thickness of L12=100 μm and being provided with the connection pads 22-30 on the upper surface is arranged at the bottom, the prepreg having the thickness of L11=60 μm is placed on said substrate 20. Then, the semiconductor chip 1 is arranged so that the corresponding connection pins 11-19 will be positioned directly above the connection pads 22-30 of the substrate 20, and the prepreg 41, having a shape molded to the configuration of said semiconductor chip 1 and having the same thickness L10=120 μm, is fitted from above. Also, for the prepreg 41, 2 prepregs of the thickness of 60 μm having a shape molded to the configuration of the semiconductor chip 1, one on top of the other, may be used. Next, the prepreg having the thickness of L9=60 μm 42 is laid down so as to cover the upper surface of the semiconductor chip 1. Lastly, the double sided substrate 50 having the thickness of L8=100 μm is placed thereon.

After the double sided substrate 50 is placed, forces are applied from opposite directions to the substrate 20 and the substrate 50 using a presser. With this, the connection pins 11-19 of the semiconductor chip 1 puncture the prepreg 40 and are coupled to the connection pads 22-30 on the substrate 20. If the prepreg is heated in this condition and is solidified, the substrate 20 and the substrate 50 are adhered to each other, and concurrently the semiconductor chip 1 is fixed between the substrates, and the multi-layered semiconductor device 55 comprising the substrate 20 and the substrate 50 is completed.

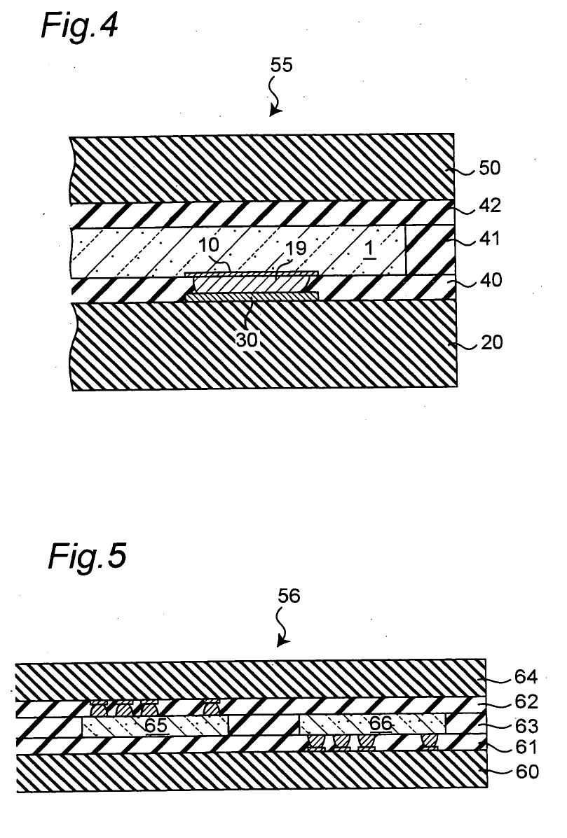

FIG. 4 is a diagram showing a cross section of a portion of the multi-layered semiconductor device 55 manufactured by the aforementioned process. As shown in the diagram, the connection pin 19 that has been mounted to the connection pad 10 of the semiconductor chip 1 has punctured the prepreg 40, and is coupled to the connection pad 30 of the substrate 20 in a state in which the tip is crushed and deformed into a trapezoidal shape. Since the position of the semiconductor is determined by the prepreg 41 that was solidified with heating, the aberration of the position of the semiconductor chip due to the expansion of the substrate after the manufacture caused by the temperature and/or warping of the substrate during the use may be effectively controlled.

For example, in the case in which an ordinary semiconductor device, in which the semiconductor chip 1 is resin molded, is mounted on the substrate with wiring, having a two-layered structure (with one prepreg of 60 μm in between), the thickness of the entirety, assuming that the thickness of the semiconductor is 1 mm, is more than 1.26 mm, whereas the thickness of the semiconductor device 55 is 440 μm, thus making it possible to control the thickness to less than a half.

Also, the prepreg 41 does not have to be present if the prepregs 40 and 42 have a high degree of flexibility and extend to the side portion of the semiconductor chip when the forces facing each other are applied to respective substrate 20 and substrate 50, and fix the semiconductor chip when said prepregs are solidified with heating.

Variation Example 1

FIG. 5 is a diagram of a cross section of a portion of the semiconductor device 56 which is a variation example 1 of the multi-layered type semiconductor device 55 relating to the Embodiment 1. The multi-layered type semiconductor device 56 has a plurality of the semiconductor chips 65 and 66 sandwiched, via prepregs 61, 62, and 63, between the multi-layered substrate comprising the substrate 60 and the substrate 64 having wiring on both sides manufactured with the same method as for the multi-layered type semiconductor device 55. In the semiconductor device 56, the connection pins mounted on the semiconductor chip 65 are mounted, as shown in the diagram, on the connection pads provided on the lower surface of the double sided substrate 64 with wiring thereon, and the connection pins mounted on the semiconductor chip 66 are mounted on the connection pads provided on the upper surface of the double sided substrate 60 with wiring thereon.

Although the thickness of the semiconductor chip 65 and the semiconductor chip 66 should basically be the same, it is possible to use those with different thickness, provided that the prepreg for filling is made available on the surface of the thinner semiconductor chip that does not have the connection pins to fill the space formed between the prepreg 61 or 62, or provided that stable connection with the substrate with wiring is not hindered even if an aperture should be formed between the prepregs 61-63.

Variation Example 2

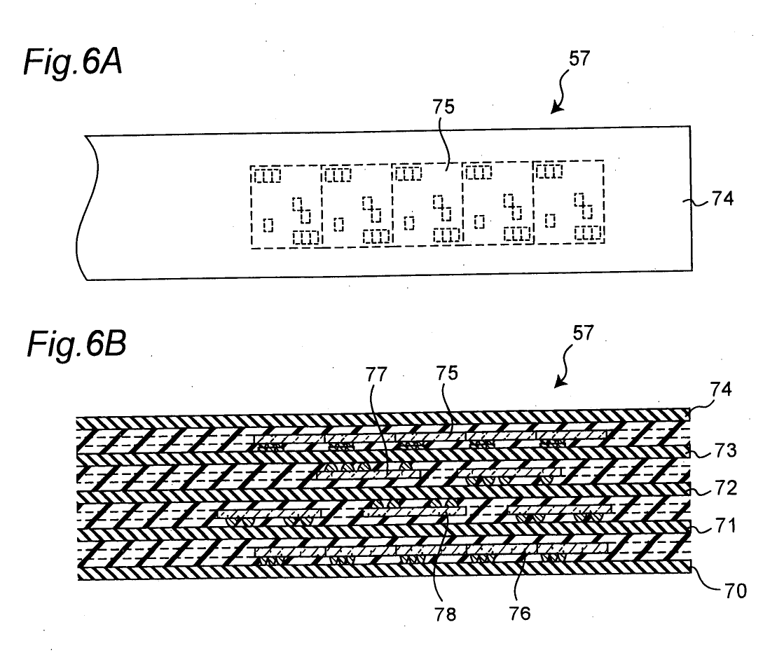

FIG. 6 is a diagram showing the structure of the semiconductor device 57, which is the variation example 2 of the stacked layer type semiconductor device 55 relating to the Embodiment 1. The semiconductor device 57 is a stacked layer type semiconductor device having 5 stacked substrates 70-74 and is characterized by 5 semiconductor chips that have not been diced sandwiched, as a group of semiconductor chips 75 and 76, between the substrate 70 and substrate 71, and between the substrate 73 and the substrate 74. With this, it is possible to eliminate the aperture between respective chips and to devise miniaturization of the devices as well as to prevent position aberration of respective chips between the substrates.

Also, as in the case of the semiconductor device 57, it is possible to form, in substance, a stacked layer structure of semiconductor chips. In the case of the semiconductor device 57, the portion in which 4 semiconductor chips are stacked one on top of the other is observed. The thickness of an ordinary semiconductor device in which the semiconductor chip is molded with resin is about 1 mm, and if 4 of them are stacked, the thickness including the lead portions and the substrate for mounting becomes more than 4 mm, whereas for the semiconductor device 57, the thickness may be controlled to approximately 1.5 mm or thereabout.

(2) Embodiment 2

The stacked layer type semiconductor device 400 relating to Embodiment 2 is characterized by changing to a thinner type with regard to the thickness of the entire multi-layered substrate with the semiconductor chips mounted thereon by preparing the semiconductor chip 100 or 150 that are provided with circuits on both surfaces.

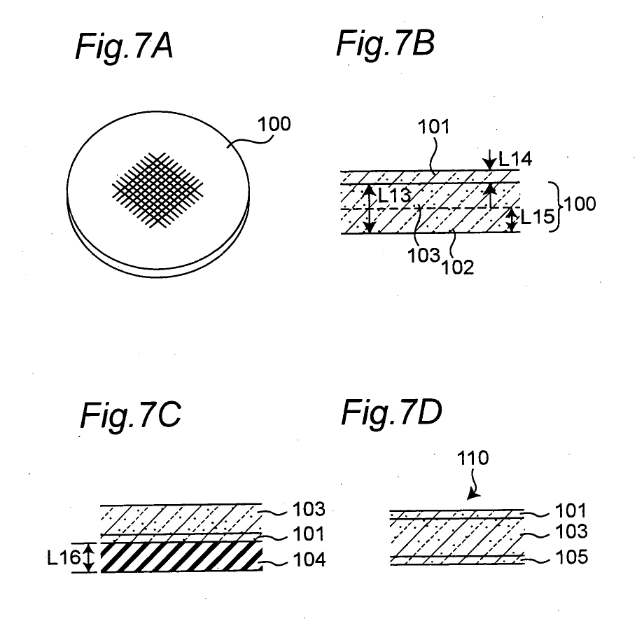

FIGS. 7A-7C are diagrams showing a manufacturing method for a semiconductor chip provided with a circuit on both surfaces. First, as shown in FIG. 7A, an integrated circuit is formed on one of the surfaces of the silicon wafer 100 through the conventional manufacturing process. Normally, since the silicon wafer 100 is manufactured on the same line as the line for other silicon wafers that do not require any consideration of the thickness thereof, its thickness is a little larger (approximately 500 μm). Generally, the silicon wafers that are required to be thinner are shaved evenly all over at the stage where the manufacture of the circuit is finished.

As shown in FIG. 7B, the integrated circuit 101 of the thickness L14=20 μm or thereabout is formed on the silicon wafer 100 having had the original thickness L13=500 μm. From the surface of the silicon wafer 100 where the circuit has not been manufactured (in the diagram, the lower surface), the region 102 having the thickness L15=4001 μm is shaved off. Hereinafter, the wafer, after said shaving process was conducted, is referred to as the silicon wafer 103. In order to form a circuit on the surface after shaving, further mechanical grinding is conducted to make the degree of smoothness to be less than 0.1 μm. Hereinafter the surface of the silicon wafer 103 on which the integrated circuit 101 is manufactured is referred to as the first surface, and the surface to which the aforementioned grinding was administered is referred to as the second surface.

As shown in FIG. 7C, the entirety of the first surface is masked with anti-oxidation plastic resin 104 with the thickness L16=150 μm so that when the second surface is rinsed with chemicals or a circuit is formed by the etching process, such processes would not affect the integrated circuit 101 formed on the first surface. With respect to said plastic resin 104, resin is used that may be removed easily without affecting the circuit on the first surface after the formation of the circuit on the second surface.

FIG. 7D is a diagram depicting a cross section of the silicon wafer 110 after the circuit 105 including the connection pads is manufactured on the second surface. With dicing of said silicon wafer 110, a semiconductor chip provided with circuits on both surfaces is completed.

In addition to the above manufacturing method, a method may be used in which the silicon wafer 100 is shaved in advance to the thinness of up to approximately 100 μm, and the circuit 101 and the circuit 105 are manufactured simultaneously on both surfaces of the silicon wafer 103 for which the removal process has been conducted. In this case, when any chemical process is conducted in a non-high temperature environment, such as the etching process, the surface to which the process is not implemented is covered with anti-oxidation plastic resin, as needed. In the case of common processes conducted in a high temperature atmosphere, the plastic resin is removed, and both surfaces are processed simultaneously. With this, it becomes possible to form more complex circuits on the second surface.

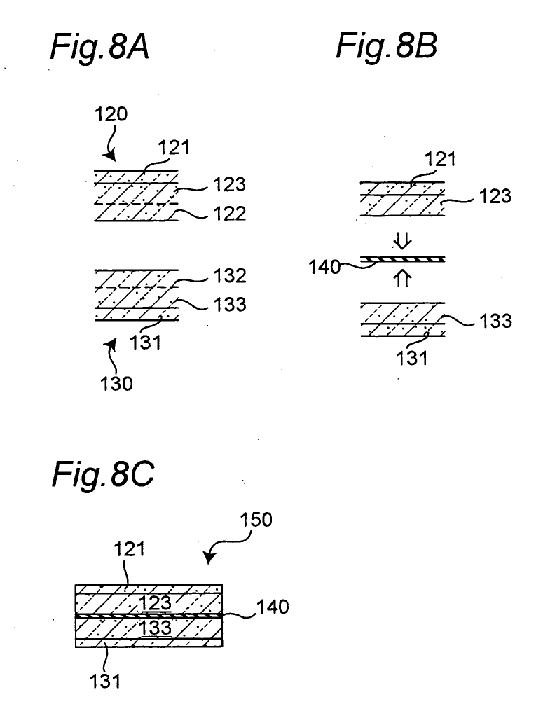

FIG. 8 shows a manufacturing method that is different from the one described above for a semiconductor chip provided with circuits on both surfaces. First, as shown in FIG. 8A, from the silicon wafers 120 and 130 having a thickness of 500 μm respectively on which the integrated circuits 121 and 131 are formed, the regions 122 and 132 in the thickness of approximately 400 μm are removed from the surfaces with no circuits manufactured thereon. Hereinafter, the silicon wafers after the removal process has been implemented are referred to as the silicon wafers 123 and 133.

As shown in FIG. 8B, after the prepreg in a non-solidified state, having electrically insulating and thermal solidifying characteristics is sandwiched between the surfaces of the silicon wafer 123 and 133 where no circuits have been manufactured thereon, heat is applied to solidify the prepreg.

FIG. 8C shows a cross section of a portion of the silicon wafer 150 manufactured in accordance with the aforementioned processes. With dicing said silicon wafer 150, a semiconductor chip provided with integrated circuits on both surfaces, is completed.

Also, in the event that the sizes of the semiconductor chips formed on the silicon wafers 120 and 130 are different, it is conceivable to dice the silicon wafers 123 and 133 after shaving has been conducted, divide them into individual semiconductors, and adhere the divided semiconductor chips using the prepreg 140.

According to said manufacturing method, there are advantages in that it is possible to shave the silicon wafers 120 and 130 to make them as thin as the strength from a manufacturing standpoint can allow, and since these are joined together via electrically insulating prepreg 140, electrical interference may be effectively prevented.

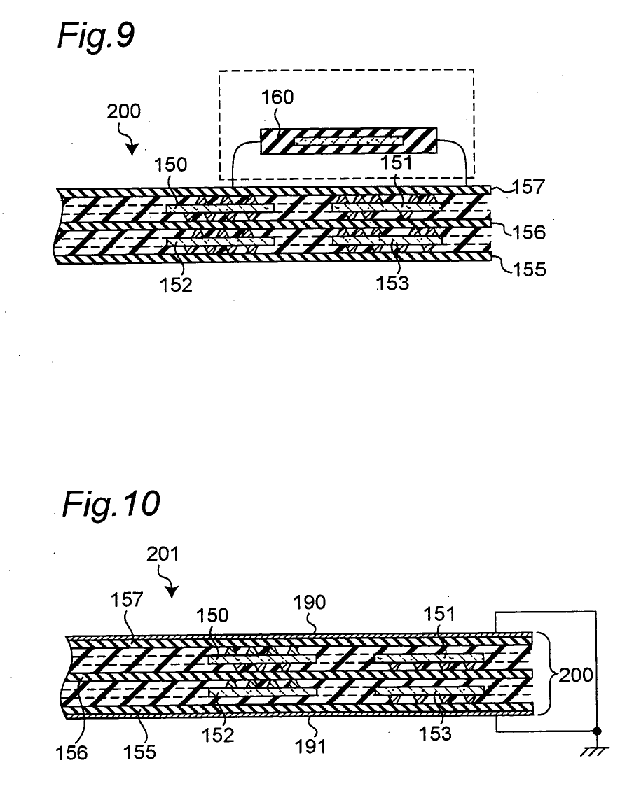

FIG. 9 is a diagram showing the structure of the stacked layer type semiconductor device 200 using semiconductor chips provided with circuits on both surfaces, which is manufactured using any of the above methods. The semiconductor device 200 is a stacked layer type semiconductor device for which the 3 substrates 155, 156, and 157 having wiring on both surfaces are stacked, the semiconductor chips 152 and 153 provided with circuits on both surfaces are provided between the substrate 155 and the substrate 156, and the semiconductor chips 150 and 151 provided with circuits on both surfaces are provided between the substrate 156 and the substrate 157. With the use of the semiconductor chips provided with circuits on both surfaces, it is possible to reduce the area occupied by semiconductor chips to one half, compared with the case in which 2 semiconductors 65 and 66 are sandwiched between the substrates in the alternate directions. Also, in comparison with the case in which 2 semiconductor chips 65 and 66 are used in an overlapping fashion, a change to a thinner semiconductor device becomes possible.

Also, since the semiconductor device 200 contains all of the necessary semiconductor chips within the multi-layered substrates in advance, an arbitrary arrangement on the substrate 157 of the semiconductor device 160 shown by the dotted line, for example, becomes possible.

In the case of an ordinary semiconductor device in which the semiconductor chip is molded using resin, problems occur even if one semiconductor chip having circuits on both surfaces that is formed by adhering 2 semiconductor chips is made available, in that it is difficult to secure the space between the leads the number of which has more or less doubled and/or to implement accurate wire-bonding of the connection pads provided on both the front and back surfaces to the corresponding leads. However, in the case of the semiconductor device under the present invention, there are advantages in that what is needed is to prepare the corresponding connection pads on the substrates that will sandwich the semiconductor chips and that the such problems as mentioned above do not arise.

FIG. 10 is a diagram showing a cross section of the semiconductor device 201, which is a variation example of the semiconductor device 200 relating to Embodiment 2. The semiconductor device 201 is characterized by the grounding pads 191 and 190, which function as noise shields for said stacked layer type semiconductor device, provided over an extensive area of the outside surfaces of the substrate 155 and the substrate 157 of the semiconductor device 200. With the adoption of said structure, it is possible to effectively prevent erroneous operation of the semiconductor chips encapsulated within the multi-layered substrates caused by outside noises. Also, it is preferable to provide the grounding pads 190 and 191 for all of the extensive area of the outside surfaces of the substrate 155 and the substrate 157. The grounding pads 190 and 191 also function as the grounding surfaces used at the time of operation of the semiconductor device.

As described above, in the case of the stacked layer type semiconductor devices 200 and 201 relating to Embodiment 2, it is possible, with the semiconductor chips provided with circuits on both surfaces available, to devise further change to make the device thin, i.e., improvement of the mounting density, in comparison with the cases of the semiconductor device 55 relating to Embodiment 1 and the semiconductor devices 56 and 57, which are variation examples of said devices.

By virtue of the features as described, the stacked layer semiconductor device under the present invention prevents the warping of the substrate and/or the aberration of the mounting position of the semiconductor chip caused by expansion/contraction of the substrate due to the temperature change by encasing the semiconductor in an electrically insulating film and fixing it.

Although the present invention has been described and illustrated in detail, it is clearly understood that the same is by way of illustration and example only and is not be taken by way of limitation, the sprit and scope of the present invention being limited only by the terms of appended claims.

What is claimed is:

1. A stacked layer type semiconductor device comprising:
a multi-layered substrate including a plurality of substrates stacked with an insulation layer in between;
a semiconductor chip having a connection pad arranged within the insulation layer lying between said plurality of substrates; and
a connection pin to electrically connect the connection pads of one substrate and the other facing substrate.

2. The stacked layer type semiconductor device according to claim 1,
wherein said semiconductor chip is provided with the connection pads on the both sides thereof.

3. The stacked layer type semiconductor device according to claim 1,
wherein the multi-layered substrate is provided with connection pads for grounding as a noise shield on the front and back surfaces thereof.

4. A method of manufacturing a stacked layer type semiconductor device, comprising the steps of
stacking a first electrically insulating layer in a non solidified state over the surface of a first substrate with a plurality of connection pads arranged thereon;
arranging a semiconductor chip with a plurality of connection pins mounted thereon so as to have respective connection pins positioned on the corresponding connection pads of the first substrate;
covering the upper portion of the semiconductor chip with a second electrically insulating layer in a non solidified state; and
stacking a second substrate on the electrically insulating layer and having the respective connecting pins penetrate through the first electrically insulating layer and electrically connect to the corresponding connecting pads of the first substrate by applying a force facing the first substrate and the second substrate.

5. The method of manufacturing a stacked layer type semiconductor device according to claim 4,
wherein said semiconductor chip is provided with the connection pads on the both sides thereof.
